(19) United States
(12) Patent Application Publication
(10) Pub. No.: US 2002/0047176 A1
(43) Pub. Date: Apr. 25, 2002

(54) Horizontal, insulated gate field effect transistor and method of driving the same

(75) Inventor: Kenichiro Takahashi, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/983,712

(22) Filed: Oct. 25, 2001

(30) Foreign Application Priority Data
Oct. 25, 2000 (JP) 2000-325232

(51) Int. Cl. H01L 31/00

(52) U.S. Cl. 257/448; 257/333; 257/371

(57) ABSTRACT

A horizontal, insulated gate field effect transistor of the present invention includes a semiconductor substrate of first conductivity. A well region of second conductivity is formed on the surface of the semiconductor substrate. A source region of first conductivity is formed in the well region. A source electrode is connected to the source region. A drain region of first conductivity is formed in the well region. A gate dielectric is formed on the well region and extends over the source region and drain region. A gate electrode is formed on the gate dielectric. The drain electrode is connected to the well region at a position other than the drain region.

### BACKGROUND OF THE INVENTION

1. Field of the Invention

The present invention relates to a horizontal, insulated gate field effect transistor (FET) for driving a capacitive load, which emits light when subjected to an electric field, and a method of driving the FET.

2. Description of the Background Art

A plasma display panel or an electroluminescence (EL) display panel includes electrodes that may be regarded as capacitive loads. The electrodes or capacitive loads are selectively charged and discharged in order to turn on and turn off desired pixels. Specifically, the individual capacitive load stores power when charged and then releases it when discharged. It has been customary with a plasma or an EL display panel to collect power discharged from the capacitive loads so as to reuse it or return it to a power source side, thereby reducing power consumption.

Conventional devices for driving a display panel include a horizontal, insulated gate FET that is a self-isolation type of semiconductor device in which impurities are introduced only via the surface of a semiconductor substrate. A horizontal, insulated gate FET can be produced at low cost. However, the problem with this type of FET is the parasitic bipolar effect that causes a current to flow to a path where power cannot be collected at the time of discharge, obstructing power saving of a display panel.

Technologies relating to the present invention are disclosed in the following documents by way of example:

(1) Japanese Patent No. 3,050,167

(2) Kenya Kobayashi et al “High Voltage SOI CMOS IC Technology for Driving Plasma Display Panels”, Proceedings of 10th International Symposium on Power Semiconductor Devices & ICs, Kyoto, 1998, pp. 141-144

(3) Japanese Patent Laid-Open Publication No. 2-210862

(4) Japanese Patent Laid-Open Publication No. 2-135781

(5) Japanese Patent Laid-Open Publication No. 1-305564

(6) Japanese Patent Laid-Open Publication No. 63-244777

(7) Japanese Patent Laid-Open Publication No. 10-335726

(8) “4.2.2 Junction-Barrier-Controlled Schottky Rectifier” “Modern Semiconductor Device Physics” edited by S. M. Sze, pp. 189-192.

### SUMMARY OF THE INVENTION

It is an object of the present invention to provide a horizontal, insulated gate FET capable of collecting power for reducing the power consumption of a display panel, and a method of driving the same.

It is another object of the present invention to provide a horizontal, insulated gate FET capable of collecting power for reducing the power consumption of a display panel without resorting to an epitaxial substrate including buried diffusion layers, an SOI (Silicon On Insulator) substrate including buried insulation layers or similar expensive component or an expensive production process, and a method of driving the same.

It is still another object of the present invention to provide a horizontal, insulated gate FET capable of reducing the power consumption and cost of a display, and a method of driving the same.

It is a further object of the present invention to provide a horizontal, insulated gate FET capable of performing switching without resorting to any switching device.

A horizontal, insulated gate FET of the present invention includes a semiconductor substrate of first conductivity. A well region of second conductivity is formed on the surface of the semiconductor substrate. A source region of first conductivity is formed in the well region. A source electrode is connected to the source region. A drain region of first conductivity is formed in the well region. A gate dielectric is formed on the well region and extends over the source region and drain region. A gate electrode is formed on the gate dielectric. The drain electrode is connected to the well region at a position other than the drain region.

A method of driving the FET described above is also disclosed.

### BRIEF DESCRIPTION OF THE DRAWINGS

The above and other objects, features and advantages of the present invention will become more apparent from the following detailed description taken with the accompanying drawings in which:

FIG. 1 is a section showing a conventional, horizontal, insulated gate FET;

FIG. 2 is a circuit diagram showing an FL display using FETs each having the conventional structure of FIG. 1;

FIG. 3 is a fragmentary section showing part of the conventional FET together with voltages and the flow of holes;

FIG. 4 is a section showing a horizontal, insulated gate FET embodying the present invention;

FIG. 5 is a circuit diagram showing an EL display using FETs each having the structure of FIG. 5;

FIG. 6 is a timing chart for describing power collection unique to the illustrative embodiment;

FIGS. 7 and 8 are fragmentary sections each showing particular voltages, a particular flow of electrons and a particular flow of holes unique to the illustrative embodiment;

FIG. 9 is a fragmentary section showing depletion layers formed in an OFF state in the illustrative embodiment;

FIG. 10 is a fragmentary section showing voltages, the flow of electrons and the flow of holes that would occur if the illustrative embodiment were used to drive a conventional horizontal, insulated gate FET;

FIG. 11 is a section showing an alternative embodiment of the present invention; and

FIG. 12 is a fragmentary section showing a drain region included in the alternative embodiment.

### DESCRIPTION OF THE PREFERRED EMBODIMENTS

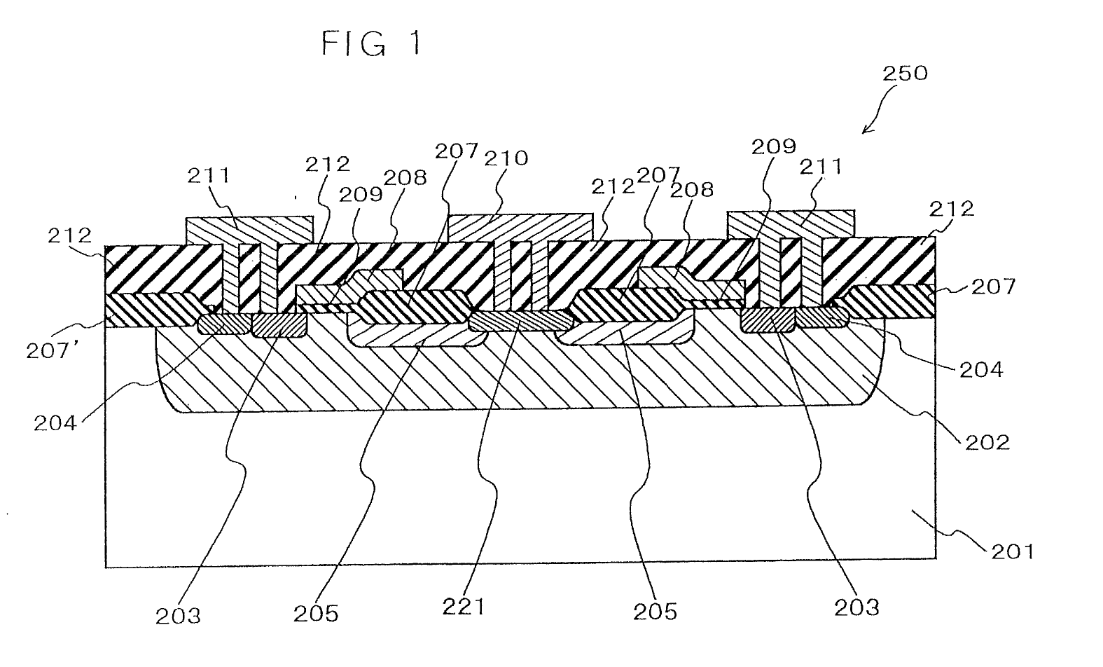

To better understand the present invention, reference will be made to a conventional horizontal, insulated gate FET, shown in FIG. 1. The horizontal, insulated gate FET to be described is a self-isolation type of semiconductor device in which impurities are introduced only via the surface of a semiconductor substrate.

As shown in FIG. 1, the horizontal, insulated gate FET, generally 250, includes a p-type semiconductor substrate 201 on which an n-type well diffusion layer 202 is formed. Two p-type source high-concentration diffusion layers 203, two n-type high-concentration diffusion layers 204 and two p-type extended drain diffusion layers 205 are formed on the n-type well diffusion layer 202. The p-type source high-concentration diffusion layers 203 each are connected to adjoining one of the n-type high-concentration diffusion layers 204. A p-type drain high-concentration diffusion layer 221 extends over one extended drain diffusion layer 205 and well diffusion layer 202 and over the other extended drain diffusion layer 205 and well diffusion layer 202.

A field oxide film 207 is formed on the extended drain diffusion layers 205. The drain high-concentration diffusion layer 221 is connected to the extended drain diffusion layers 205 and field oxide film 207. A gate oxide film 209 is formed on the well diffusion layer 202 and source high-concentration diffusion layers 203 and connected to the field oxide film 207. A gate electrode 208 is formed on the field oxide film 207 and gate oxide film 209. A field oxide film 207′ is formed on the semiconductor substrate 201 and well diffusion layer 202 and connected to the high-concentration diffusion layer 204. The field oxide films 207 and 207′ are formed by a single step.

An interlayer dielectric-21 is formed on the source high-concentration diffusion layers 203, high-concentration diffusion layers 204, field oxide layers 207 and 207′, gate electrode 208, and drain high-concentration diffusion layer 221. The interlayer dielectric 212 is connected to the source high-concentration diffusion layers 203, high-concentration diffusion layers 204, field oxide film 207′, gate electrode 208, gate oxide film 209, and drain high-concentration layer 221.

Holes are formed throughout the inter layer dielectric 212, so that a source electrode 21 can be connected to the surfaces of the source high-concentration diffusion layers 203 and high-concentration diffusion layers 204. Also formed throughout the interlayer dielectric 212 are holes for connecting the drain electrode 210 to the surfaces of the drain high-concentration diffusion layer 221.

The source electrode 211 is formed on the surface of the interlayer dielectric 212 and connected to the high-concentration diffusion layers 203 and 204. The drain electrode 210 is also formed on the surface of the interlayer dielectric 212 and connected to the drain high-concentration diffusion layer 221.

The structure shown in FIG. 1 implements a horizontal, high voltage, p-channel insulated gate FET embracing the n-type well diffusion layer 202. In this type of FET, the drain electrode 210 is electrically connected to the drain high-concentration diffusion layer 221, which covers the entire drain region where the field oxide film 207 is absent.

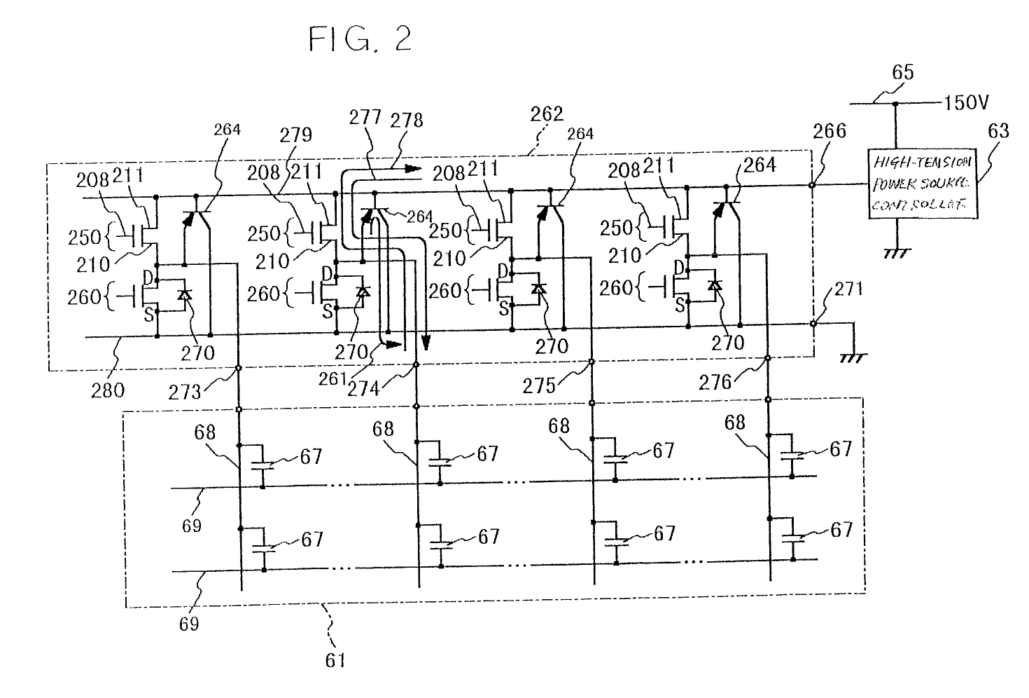

Reference will be made to FIG. 2 for describing an EL display using horizontal, insulated gate FETs each having the conventional configuration shown in FIG. 1. As shown, the EL display is generally made up of an EL display panel 61, a semiconductor unit 262 for driving the display panel 61, and a high-tension power source controller 63. In practice, several hundred EL display panels 61 are arranged in lattice arrays vertically and horizontally at preselected intervals.

The EL display panel 61 includes scanning line electrodes 68 and data line electrodes 69 extending vertically and horizontally, respectively. These two groups of electrodes 68 and 69 form pixels at points where they intersect each other. The EL display, as well as a plasma display, selectively generates strong electric fields between the scanning line electrodes 68 and the data line electrodes, thereby emitting light. Therefore, each pixel necessary involves a great parasitic capacitance 67. The semiconductor unit 262 drives the EL display panel 61 and thereby causes the EL display or a plasma display to emit light.

A high-tension constant voltage source 65 and the semiconductor unit 262 are connected to the high-tension power source controller 63, which is connected to ground at one end. The power source controller 63 transforms a high constant voltage input from the power source 65 to a periodic rectangular wave. The power source controller 63 applies the voltage, i.e., the rectangular wave to the semiconductor unit 262 via a high-tension power source terminal 266, allowing the semiconductor unit 262 to drive the EL display panel 61. The rectangular wave periodically rises from 0 V to 150 V. Power is collected when the voltage applied to the semiconductor unit 262 is dropping from 150 V to 0 V.

The power source controller 63 and EL display panel 61 are connected to the semiconductor unit 262, which is connected to ground at one end. The power source controller 63 applies 150 V to a high-tension power source line 279 included in the semiconductor unit 262 via the high-tension power source terminal 266. Let this voltage be referred to as a high-tension power source VDD hereinafter. The semiconductor unit 262 includes several hundred high-voltage CMOS (Complementary Metal Oxide Semiconductor) transistors in an array. The CMOS transistors are implemented by the conventional horizontal, insulated gate FETs 250 (sometimes referred to as PMOS (p-channel MOS) transistors hereinafter) and NMOS (n-channel MOS) transistors 260.

The source 211 of each PMOS transistor 250 is connected to the high-tension power source line 279, so that 150 V input from the power source controller 63 is applied to the source electrode 211. Each NMOS transistor 260 has a source electrode S connected to ground via a low-tension power source line 280. A voltage applied to the low-tension power source line 280 is assumed to be a low-tension power source VSS hereinafter. A parasitic diode or so-called body diode 270 exists between the drain electrode D and the source electrode S of each NMOS transistor 260 due to the structure of diffusion layers.

A PMOS control circuit and an NMOS control circuit neither one of which is shown in FIG. 2 are connected to the semiconductor unit 262. The PMOS control circuit applies a periodic voltage to the gate electrodes 208 of the PMOS 250 transistors 250. In this case, the gate of each PMOS transistor 250 turns on when connected to ground or turns off when applied with 150 V. It should be noted that in the EL display using the conventional FETs 250, the gate of each PMOS transistor 260 usually remains in an OFF state.

To charge any one of the electrodes of the EL display panel 61, the semiconductor unit 262 outputs a charge current 277 that flows from the drain electrode 210 of the PMOS transistor 250 associated with the subject electrode to the display panel 61. The EL display panel 61 charges the subject electrode with the charge current 277. Also, the EL display panel 61 outputs a discharge current 278 as a current that flows when the subject electrode is caused to discharge. The discharge current 278 is input to the semiconductor unit 262. More specifically, the discharge current 278 is routed through the drain electrode 210 of the PMOS transistor 250, the source electrode 211 of the same transistor 250 and the high-tension power source controller 63 and then collected by the high-tension power source 65.

A high voltage CMOS transistor (PMOS transistor 250 and NMOS transistor 260) includes a parasitic bipolar transistor 264 due to it& structure. Several hundred parasitic bipolar transistors 264 are arranged in an array in the same manner as the CMOS transistors. Each parasitic bipolar transistor 264 has an emitter electrode connected to the drain electrode 210 of the associated PMOS transistor 250 and the drain electrode D of the associated NMOS transistor 260. The base electrode of the parasitic bipolar transistor 264 is connected to the high-tension power source line 279. Further, the collector electrode of the parasitic bipolar transistor 264 is connected to the low-tension power source line 280. Such parasitic bipolar transistors 264 have critical influence on the power consumption of the EL display.

The document (1) mentioned earlier discloses a semiconductor device constructed to reduce the power consumption of an EL display panel or a plasma display panel. The semiconductor device constitutes an FET of first conductivity type including a semiconductor substrate of first conductivity, a well diffusion layer of second conductivity formed on the surface of the semiconductor substrate, and a drain diffusion layer of first conductivity formed in the well diffusion layer. When a current flows forward between the drain diffusion layer and well diffusion layer, a first semiconductor switching device serially connected to the semiconductor substrate electrically opens the substrate. With this configuration, the semiconductor device intercepts a current flowing toward the side where the switching device cannot collect power at the time of power collection. The above document addresses power collection, deterioration of power collection efficiency ascribable to the parasitic bipolar effect particular to a self-isolation type of semiconductor device, and improvement in the power collection efficiency of a semiconductor device of the type using an epitaxial substrate that includes buried high-concentration diffusion layers.

The document (2) also mentioned earlier describes the advantages of a substrate including buried insulation films (SOI substrate) with respect to the enhancement of power collection efficiency.

The document (3) teaches a semiconductor device configured to suppress parasitic bipolar transistor operation for thereby obviating, e.g., latch-up. Specifically, the semiconductor device includes an insulated gate FET (MOSFET (Metal Oxide Semiconductor FET) hereinafter) in which a channel region is split into a plurality portions. A drain current is fed via a region mainly extending from the surface toward the inside of a semiconductor substrate and a high-concentration region formed in the substrate. The device causes a current to flow from the surface of the semiconductor device toward the inside of the same.

The document (4) discloses a vertical, insulated gate semiconductor device that does not include a parasitic thyristor and is therefore free from latch-up. This semiconductor device is a semiconductor device of first conductivity. A buried insulation layer is formed in a substrate at a preselected depth, as measured from the surface of the substrate, and formed with a hole. A metal electrode is positioned on part of the surface of the substrate that substantially faces the above hole, forming a Schottky junction. The Schottky junction may be replaced with a junction formed by a layer of second conductivity formed on the surface of the substrate. A channel region is isolated from the surface of the substrate by a buried insulation layer. A gate is formed on the channel region with the intermediary of a dielectric film. A high-concentration region of firstconductivity is electrically connected to the channel region. The semiconductor device controls a voltage barrier between the substrate and the metal electrode or between the substrate and the layer of second conductivity with a voltage applied to the gate. Consequently, the injection and interception of carriers is controlled between the high-concentration region of first conductivity or source and the substrate or drain.

The document (5) proposes a semiconductor IC circuit configured to control an invalid current ratio to a degree acceptable in practice for thereby insuring stable operation. The semiconductor IC circuit includes an n-type buried diffusion layer formed in the desired region of a p-type substrate. An n-type layer is formed on the buried diffusion layer. A Schottky barrier type of diode is formed in a discrete device region surrounded by a p-type diffusion layer. A p-type guardring portion is positioned around the barrier metal of the diode. An n-type guardring portion is formed in the diffusion layer region of the p-type guardring portion.

The document (6) discloses a MOS FET configured to obviate breakdown ascribable to the operation of a parasitic bipolar transistor without making control over a gate threshold voltage difficult. The MOS FET includes a drain region implemented by a semiconductor region of first conductivity. A base region is implemented by a semiconductor region of second conductivity formed on the surface portion of the drain region. A source region is implemented by a semiconductor region of first conductivity formed in the surface portion of the base region. A gate electrode is formed on the base region between the drain region and the source region via a gate oxide film. The source region is formed by the Schottky junction of a low-concentration diffusion layer and a metal layer.

As shown in FIG. 2, in the EL display using the conventional FETs 250, the discharge current 278 sparingly flows from the semiconductor unit 262 to the high-tension power source controller 63. Instead, a current 261 flows due to the operation of the parasitic bipolar transistor 264. The current 261 corresponds to power that cannot be collected at the time of discharge.

In the EL display, most power stored in the capacitive components can be collected if the current amplification ratio of the individual parasiticbipolar transistor 264 is small. In this sense, the parasitic bipolar transistors 264 should preferably operate as diodes that reduce the current amplification ratio to zero. However, the self-isolation type of structure, which is easy to form, cannot avoid a relatively great current amplification ratio.

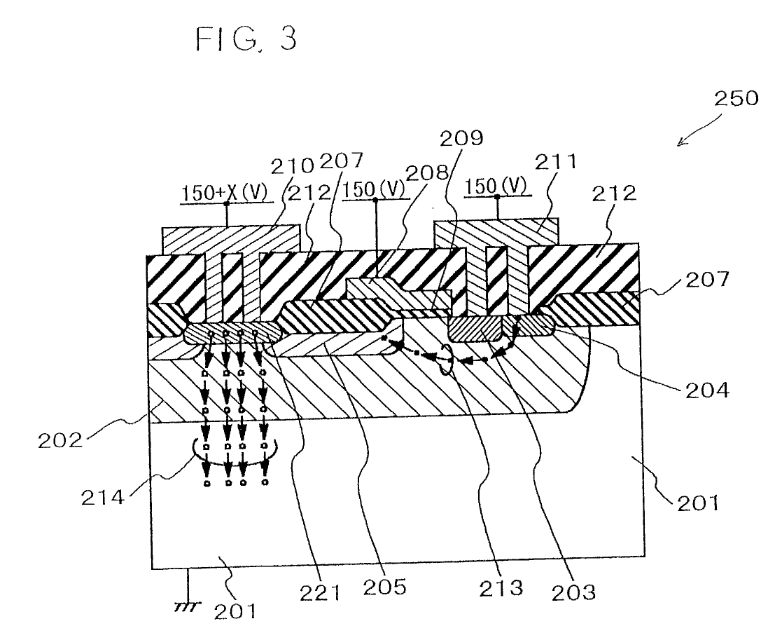

Reference will be made to FIG. 3 for describing the current 261 ascribable to the operation of the parasitic bipolar transistor 264 more specifically. As shown, 150 V is applied to the gate electrode 208 and source electrode 211 of the conventional FET 250. 150 V plus X V (X being a real number) higher than 150 V appears on the drain electrode 210. It is a common practice to collect power by forcibly causing a current to flow from the drain toward the source. Holes are injected from the p-type drain high-concentration diffusion layer 221 into the n-type well diffusion layer 202 due to the parasitic bipolar effect. However, the holes are propagated mainly through the well diffusion layer 202 due to a diffusion mechanism and flow toward the p-type semiconductor substrate 201, as indicated by arrows 214 in FIG. 3. While holes flowing toward the source electrode 211 allow power to be collected, the flow of holes 214 toward the substrate 201 is not the subject of power collection. The flow of holes 214 corresponds to the current 261 ascribable to the operation of the parasitic bipolar transistor 264. At this instant, electrons flow from the source electrode 211 toward the p-type extended drain diffusion layer 205 via the high-concentration diffusion layer 204 and diffusion layer 202.

A forward current at a pn junction flows due to the injection of a small number of carriers and does not include any other current component. A ratio between the amount of electrons and that of holes constituting the forward current is substantially proportional to the concentration ratio between diffusion layers where the electrons and holes are originated. It follows that the amount of holes is several times as great as the amount of electrons. Further, almost all of the holes injected into the n-type well diffusion layer 202 reach the substrate 201 due to the geometric structure of the diffusion layer and because the time necessary for the holes to pass the well diffusion layer 202 is far shorter than a recombination lifetime. Consequently, more than one-half of the current flows from the drain electrode 210 to the substrate 201 without being collected.

Although the conventional FET 250 is low cost, it causes a current to flow to a path where power cannot be collected at the time of discharge due to the parasitic bipolar effect and thereby obstructs power saving of a display panel, as stated earlier.

The semiconductor device taught in the document (1) is capable of collecting sufficient power to thereby reduce the power consumption of a display panel. However, the semiconductor device is more expensive than the conventional FET 250, which is a self-isolation type of semiconductor device. The semiconductor device taught in the document (1) intercepts a current flowing toward the non-collectable path with a switching device. This, however, brings about a loss ascribable to the switching of the switching device. More specifically, charge and discharge occur up to the low-tension power source line and prevent power form being collected. The loss is aggravated by errors in switching timing. Moreover, the semiconductor device needs extra switching devices.

Preferred embodiments of the horizontal, insulated gate FET in accordance with the present invention will be described hereinafter.

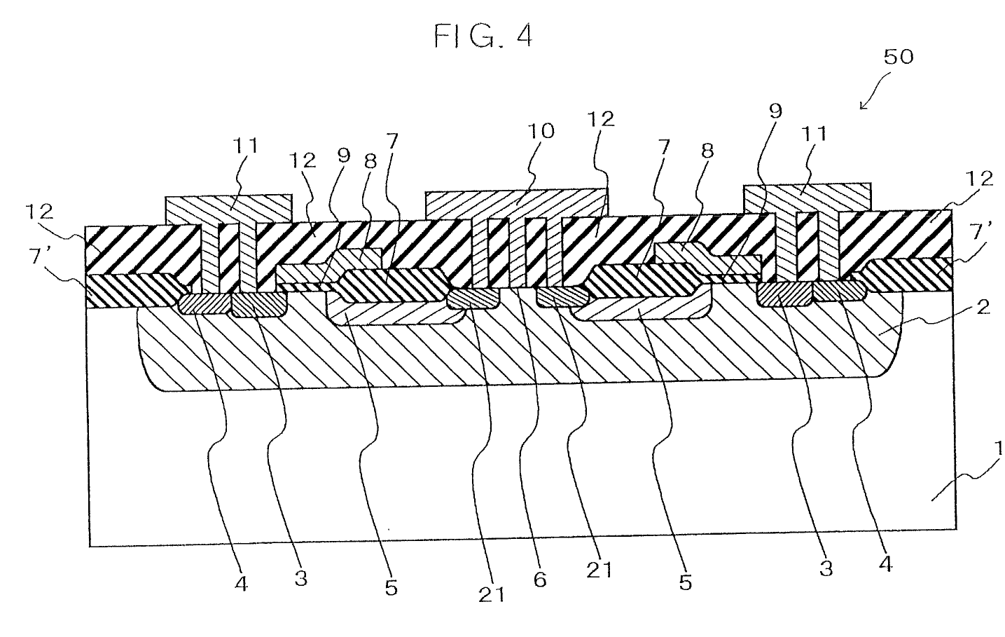

Referring to FIG. 4, a horizontal, insulated gate FET embodying the present invention is shown and generally designated by the reference numeral 50. As shown, the FET includes a p-type semiconductor substrate 1 in which boron is uniformly doped in a concentration of about 7×10¹⁴/cm³. Phosphor bronze is doped in the surface of the substrate 1 to a junction depth of 8 μm to 14 μm in a concentration of about 5×10¹⁵/cm³, forming an n-type well diffusion layer 2. Two p-type source high-concentration diffusion layers 3, two n-type high-concentration diffusion layers 4 and two p-type extended drain diffusion layers 5 are formed on the surface of the well diffusion layer 2. The source high-concentration diffusion layers 3 and high-concentration diffusion layers 4 are connected to each other.

A p-type drain high-concentration diffusion layer 21 is formed on the surface of the well diffusion layer 2 and that of one of the extended drain diffusion layers 5. Another p-type drain high-concentration diffusion layer 21 is formed on the surface of the well diffusion layer 2 and that of the other extended drain diffusion layer 5. Neither one of the two drain high-concentration diffusion layers 21 exists in part of the surface of the well diffusion layer 2, as illustrated.

A field oxide film 7 is formed on the surfaces of the drain diffusion layers 5. The drain high-concentration diffusion layers 21 are connected to the extended drain diffusion layers 5 and field oxide film 7. A gate oxide film 9 is formed on the surface of the well diffusion layer 2 and the surfaces of the source high-concentration diffusion layers 3 and connected to the field oxide film 7. A gate electrode 8 is formed on the surface of the field oxide film 7 and that of the gate oxide film 9. Another field oxide layer 7′ is formed on the surface of the substrate 1 and that of the well diffusion layer 2 and connected to the high-concentration diffusion layers 4. The field oxide layers 7 and 7′ are formed by a single step.

An interlayer dielectric 12 is formed on the source high-concentration diffusion layers 3, high-concentration diffusion layers 4, field oxide layers 7 and 7′, gate electrode 8 and drain high-concentration diffusion layers 21. The interlayer dielectric 3 is connected to the well diffusion layer 2, high-concentration diffusion layers 3, high-concentration diffusion layers 4, field oxide layer 7′, gate electrode 8, gate oxide layer 9, and drain high-concentration layers 21.

Holes are formed throughout the interlayer dielectric 12 for connecting the surfaces of the source high-concentration diffusion layers 3 and those of the high-concentration diffusion layers 4 to a source electrode 11. Other holes are formed throughout the interlayer dielectric 12 for connecting the drain high-concentration diffusion layers 21 to a drain electrode 10. Further, a hole is formed throughout the interlayer dielectric 12 for connecting the well diffusion layer 2 and drain electrode 10, so that a Schottky barrier is formed.

The source electrode 11 is formed on the surface of the interlayer dielectric 12 and connected to the source high-concentration diffusion layers 3 and high-concentration diffusion layers 4. The drain electrode 10 is also formed on the surface of the interlayer dielectric 12 and connected to the drain high-concentration diffusion layer 21. The drain electrode 10 is connected to the well diffusion layer 2 as well, constituting a Schottky barrier forming portion 6.

In the structure shown in FIG. 4, a horizontal, high voltage, p-channel insulated gate FET is formed on the surface of the n-type well diffusion layer 2.

Ohmic electric connection is set up between the drain electrode 10 and the drain high-concentration diffusion layer 21. At the same time, the drain electrode 10 is directly connected to the well diffusion layer 2, forming a Schottky barrier. The Schottky barrier forming portion 6 is surrounded by the drain high-concentration diffusion layers 21 in the form of an island.

The drain high-concentration diffusion layer 21 is connected to the extended drain diffusion layers 5, as stated above. The extended drain diffusion layers 5 are formed below the field oxide layer 7 by self-alignment in order to insure a high breakdown voltage between the drain and the source. When the FET is turned off, the layers 5 are depleted in accordance with a voltage applied and accommodate substantially the entire high voltage between the drain and the source. The layers 5 each are provided with a high impurity concentration and a small horizontal length within a range allowable in relation to the required breakdown voltage from the ON-resistance standpoint, although such factors depend on the required breakdown voltage.

Extending from the center portion of the drain, the extended drain diffusion layers 5 each adjoin at one end thereof a gate region where an insulated gate mechanism having the gate electrode 8 and gate oxide film 8 on its surface is formed. The side of the gate region opposite to the drain region adjoins a source region where the source high-concentration diffusion layer 3 is positioned on well diffusion layer 2. Ohmic electric connection between the source high-concentration diffusion layer 3 and source electrode 11 feed a current to the diffusion layer 3. The source electrode feed a current to the well diffusion layer 2 by the ohmic connection thereof to the high-concentration diffusion layer 4, which is formed on the surface of the well diffusion layer 2.

A specific contact/plug type of procedure for producing the horizontal, insulated gate FET 50 will be described hereinafter. Briefly, as shown in FIG. 4, the contact/plug type of procedure sets up electric connection between the source electrode 11 and drain electrode 10 formed on the surface of the laminate and the well diffusion layer or semiconductor layer 2.

The interlayer dielectric 12 is grown on the surface of the well diffusion layer 2. Subsequently, holes are formed in the portions of the interlayer dielectric 12 above the source high-concentration diffusion layers 3, high-concentration diffusion layers 4 and drain high-concentration diffusion layers 21 by selective photolithography. After tungsten or similar metal has been grown on the interlayer dielectric 12, it is etched back and left only in the above holes thereby. The source electrode 11 and drain electrode 10 are selectively formed on the interlayer dielectric 12 in such a manner as to be connected to tungsten filling the holes. As a result, the source electrode 11 is connected to the source high-concentration diffusion layers 3 and high-concentration diffusion layers 4. Likewise, the drain electrode 10 is connected to the drain high-concentration diffusion layer 21 and well diffusion layer 2. For the electrodes 10 and 11, use is made of aluminum or similar metal.

The latest fine, low-voltage CMOS devices are produced by the contact/plug type of procedure described above. In this respect, the structure of the horizontal, insulated gate FET 50 shown in FIG. 4 is feasible for applications of the kind arranging the FETs 50 and fine, low-voltage SMOS devices on a single semiconductor substrate. For example, when the FETs 50 are applied to a plasma display or an EL display, they can drive the electrodes of the display without resorting to an epitaxial substrate including buried diffusion layers or an SOI substrate including buried dielectric layers. The illustrative embodiment therefore noticeably reduces the production cost of the display.

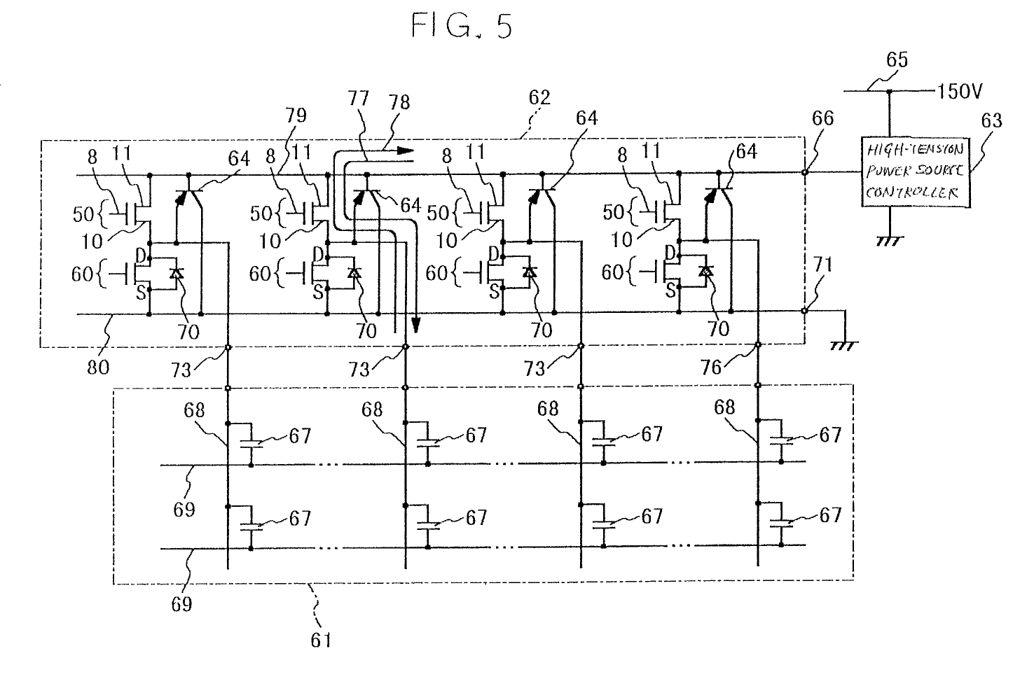

Reference will be made to FIG. 5 for describing an EL display using horizontal, insulated gate FETs 50 each having the configuration shown in FIG. 4. As shown, the EL display is generally made up of an EL display panel 61, a semiconductor unit 62 for driving the display panel 61, and a high-tension power source controller 63. In practice, several hundred EL display panels 61 are arranged in lattice arrays vertically and horizontally at preselected intervals.

The EL display panel 61 includes scanning line electrodes 68 and data line electrodes 69 extending vertically and horizontally, respectively. These two groups of electrodes 68 and 69 form pixels at points where they intersect each other. The EL display, as well as a plasma display, selectively generates strong electric fields between the scanning line electrodes 68 and the data line electrodes, thereby emitting light. Therefore, each pixel necessary involves a great parasitic capacitance 67. The semiconductor unit 62 drives the EL display panel 61 and thereby causes the EL display or a plasma display to emit light.

A high-tension constant voltage source 65 and the semiconductor unit 62 are connected to the high-tension power source controller 63, which is connected to ground at one end. The power source controller transforms a high constant voltage input from the power source 65 to a periodic rectangular wave. The power source controller 63 applies the voltage, i.e., the rectangular wave to the semiconductor unit 62 via a high-tension power source terminal 66, allowing the semiconductor unit 62 to drive the EL display panel 61. The rectangular wave periodically rises from 0 V to 150 V. Power is collected when the voltage applied to the semiconductor unit 62 is dropping from 150 V to 0 V.

The power source controller 63 and EL display panel 61 are connected to the semiconductor unit 62, which is connected to ground at one end. The power source controller 63 applies 150 V to a high-tension power source line 79 included in the semiconductor unit 62 via the high-tension power source terminal 66. Let this voltage be referred to as a high-tension power source VDD hereinafter. The semiconductor unit 62 includes several hundred high-voltage CMOS transistors, i.e., the FETs 50 of the illustrative embodiment (sometimes referred to as PMOS transistors 50 hereinafter) in an array.

The source electrode 11 of each PMOS transistor 50 is connected to the high-tension power source line 79, so that 150 V input from the power source controller 63 is applied to the source electrode 11. Each NMOS transistor 60 has a source electrode S connected to ground via a low-tension power source line 80. A voltage applied to the low-tension power source line 80 is assumed to be a low-tension power source VSS hereinafter. A parasitic diode or body diode 70 exists between the drain electrode D and the source electrode S of each NMOS transistor 60 due to the structure of diffusion layers.

A PMOS control circuit and an NMOS control circuit neither one of which is shown in FIG. 5 are connected to the semiconductor unit 62. The PMOS control circuit applies a periodic voltage to the gate electrodes 8 of the PMOS transistors 50. In this case, the gate of each PMOS transistor 50 turns on when connected to ground or turns off when applied with 150 V. It should be noted that in the EL display using the conventional FETs 50, the gate of each PMOS transistor 60 usually remains in an OFF state.

To charge any one of the electrodes of the EL display panel 61, the semiconductor unit 62 outputs a charge current 77 that flows from the drain electrode 10 of the PMOS transistor 50 associated with the subject electrode to the display panel 61. The EL display panel 61 charges the subject electrode with the charge current 77. Also, the EL display panel 61 outputs a discharge current 78 as a current that flows when the subject electrode is caused to discharge. The discharge current 78 is input to the semiconductor unit 62. More specifically, the discharge current 78 is routed through the drain electrode 10 of the PMOS transistor 50, the source electrode 11 of the same transistor 50 and the high-tension power source controller 63 and then collected by the high-tension power source 65.

A high-voltage CMOS transistor (PMOS transistor 50 and NMOS transistor 60) includes a parasitic bipolar transistor 64 due to its structure. Several hundred parasitic bipolar transistors 64 are arranged in an array in the same manner as the CMOS transistors. Each parasitic bipolar transistor 64 has an emitter electrode connected to the drain electrode 10 of the associated PMOS transistor 50 and the drain electrode D of the associated NMOS transistor 60. The base electrode of the parasitic bipolar transistor 64 is connected to the high-tension power source line 79. Further, the collector electrode of the parasitic bipolar transistor 64 is connected to the low-tension power source line 80.

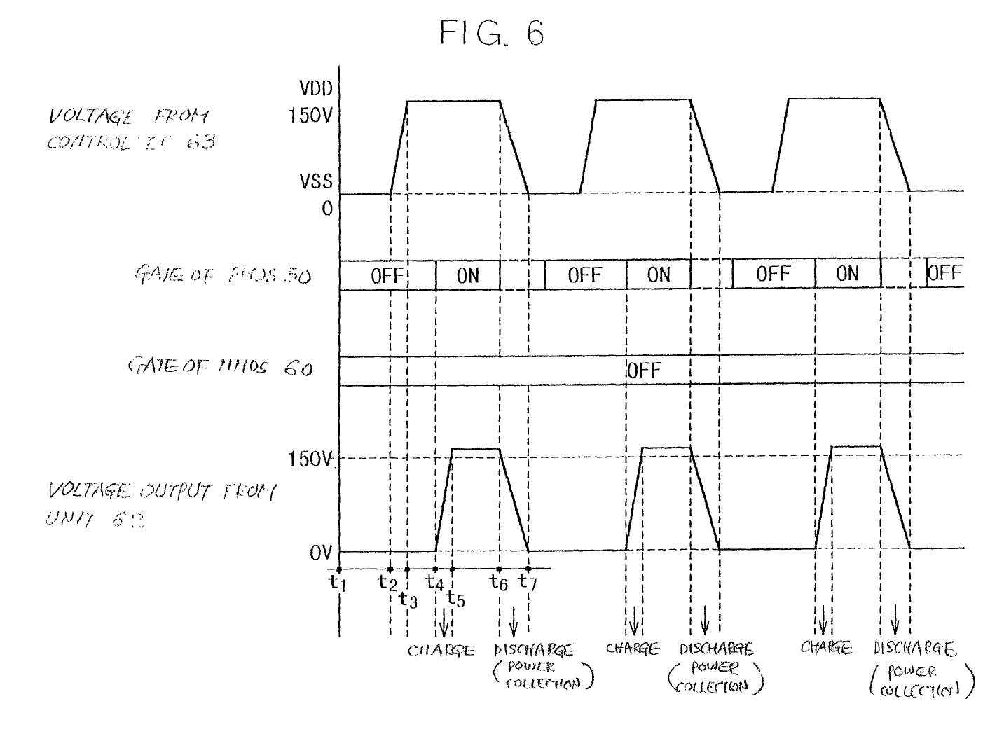

How the EL display using the FETs (PMOS transistors) 50 of the illustrative embodiment collects power will be described with reference to FIGS. 6. As shown, the voltage applied to the semiconductor unit 62 is a rectangular wave periodically rising from 0 V to 150 V. One period of the rectangular wave extends from a point t1 to a point t7. The periodic variation of the voltage from 0 V to 150 V will be referred to as switching hereinafter. Also, the interval between points 1 and 6 over which 150 V is continuously applied to the semiconductor unit 62 will be referred to as a switching time. Further, the interval between points t4 and t5 over which the display panel 61 charges the current 77 output from the semiconductor unit 62 will be referred to as a charging time. Furthermore, an interval between the points t6 and t7 over which the display panel 61 discharges the discharge current 78 to the semiconductor unit 62 will be referred to as a discharging time. In addition, the interval over which the voltage applied to the semiconductor unit 62 drops from 150 V to 0 V will be referred to as a switching-out time or power collecting time. Power is collected during the switching-out time.

First, from the point p1 to a point p2, the high-tension power source VDD is 0 volt, i.e., the potential difference between the high-tension power source VDD and the low-tension power source VSS is 0 V. Such a relation between the voltage of the high-tension power source VDD and the potential difference will not be repeatedly stated in order to avoid redundancy. In this condition, the gate of the PMOS transistor 50 and the gate of the NMOS transistor 60 both remain in an OFF state.

From the point p2 to the point p3, the high-tension power source VDD rises from 0 V to 150 V. At this instant, if the gate of the PMOS transistor 50 and that of the NMOS transistor 60 are in an OFF state, then the semiconductor unit 62 does not apply any voltage to the display panel 61.

During the switching time, i.e., from the point t3 to the time t6, the high-tension power source VDD remains at 150 V. Because the gate of the PMOS transistor 50 and that of the NMOS transistor 60 are in an OFF state from the point t3 to the point t4, the semiconductor unit 62 does not output any voltage to the display panel 61.

At the point t4, the gate of the PMOS transistor 50 turns on. At this instant, the high-tension power source VDD is 150 V while the gate of the NMOS transistor 60 is still in an OFF state. Consequently, the semiconductor unit 62 applied with 150 V feeds a voltage higher than 150 V and a charge current 77 to the display panel 61 via the high voltage CMOS and the “i” output terminal 73. During the charging time, i.e., from the point t4 to the point t5, the display panel 61 charges the charge current 77 when the output voltage of the semiconductor rises 62 rises from 0 V to 150 V.

From the point t5 to the point t6, the semiconductor unit 62 continuously outputs 150 V because its voltage is 150 V and because the gate of the PMOS transistor 50 and that of the NMOS transistor 60 are in an ON state and an OFF state, respectively.

During the discharging time or power collecting time, i.e., from the point t6 to the point t7, the high-tension power source VDD drops from 150 V to 0 V. At this time, the gate of the PMOS transistor 50 is in an ON state (or may be in an OFF state) while the gate of the NMOS transistor 60 is an OFF state. As a result, the output voltage of the semiconductor unit 62 drops from 150 V to 0 V. During the discharging time and power collecting time, the display panel 61 discharges a discharge current 78 when the output voltage of the semiconductor unit 62 drops from 150 V to 0 V. The discharge current 78 flows from the drain gate 10 of the PMOS transistor 50 to the high-tension power source 65 via the source electrode 11 of the transistor 50 and high-tension power source controller 63 and collected by the power source 65.

The EL display using the FETs (PMOS transistors) 50 of the illustrative embodiment collects power while repeating the procedure beginning at the point t1 and ending at the point t7. The power mentioned above refers to the product of the voltage fed from the high-tension power source 65 and discharge current 78.

It has been customary with an EL display to collect power by raising the output voltage above the high-tension power source VDD. By contrast, the EL display using the horizontal, insulated gate FET 50 is capable of collecting power by lowering the high-tension power source VDD from 150 V to 0 V.

If desired, the EL display using the horizontal, insulated gate FET 50 may collect power by momentarily inducing a voltage higher than the high-tension power source VDD on the “i” output terminal 74 via a coil at the time of turn-off.

The EL display using the horizontal, insulated gate FET 50 is operable in a positive-polarity charging mode. A negative-polarity charging mode is also available with the illustrative embodiment. In the negative-polarity charging mode, the EL display with the configuration of FIG. 5 operates in the same manner except that −150 V and 0 V are assigned to the high-tension power source VDD and low-tension power source VSS, respectively. Further, the EL display may alternately operate in the positive-polarity and negative-polarity charging modes in order to extend the service life of the display panels. In such a case, it is preferable to constantly turn off the NMOS transistor 60 in the positive-polarity charging mode and to constantly turn off the PMOS transistor 60 in the negative-polarity charging mode while controlling the NMOS transistor 60 ON and OFF for charge/discharge control.

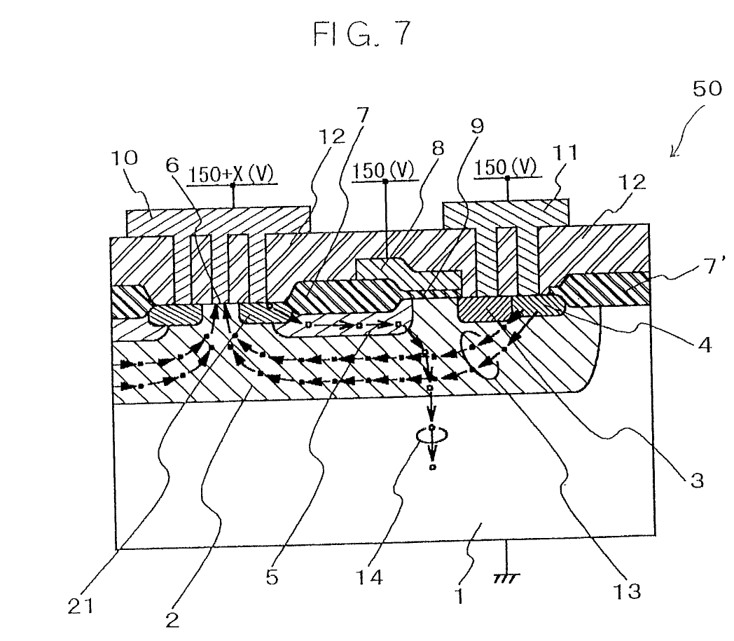

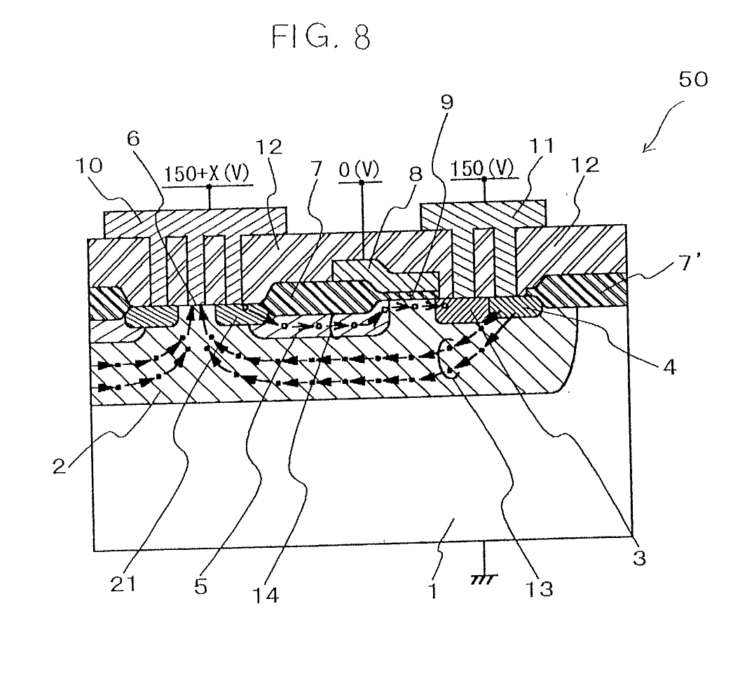

Reference will be made to FIGS. 7 and 8 for describing specific methods of driving the horizontal, insulated gate FET 50 and the collection of power on the assumption of a plasma display or an EL display. FIGS. 7 and 8 each show only one of opposite portions of the FET 50 with respect to the drain region because the two portions are symmetrical to each other. In FIG. 4 and FIGS. 7 and 8, identical reference numerals designate identical structural elements. FIGS. 7 and 8 are identical with each other except for the condition of application of a bias.

As shown in FIGS. 7 and 8, the p-type semiconductor substrate of the FET 50 is connected to ground. The n-type well diffusion layer 2 and p-type source high-concentration diffusion layer 3 are fed from the high-tension power source (150 V) via the source electrode 11. 150 V and 0 V each are periodically fed to the source electrode 11 due to the switching of the high-tension power source controller 63, FIG. 5. During usual switching time over which 150 V is applied, the gate electrode 8 is biased. For example, to turn on the gate, a bias is applied to the gate electrode 8 to thereby connect it to ground. To turn off the gate, 150 V is applied to the gate electrode 8. Further, because the FET 50 is of p-channel type, the size of a drain current to flow from the source to the drain is control led. The power collecting time does not coincide with the usual switching time. In addition, the current to flow between the drain and the source is forcibly made opposite in direction (from the drain to the source) to the current to flow during usual switching time by outside control.

First, reference will be made to FIG. 7 for describing power collection effected by applying 150 V to the gate electrode 8. In the following description, the FET 50 is assumed to be in an OFF state when 150 V is applied to the gate electrode 8. As shown, 150 V is applied to the gate electrode 8 and source electrode 11 of the FET 50. 150 V plus X V is applied to the drain electrode 10.

To collect power, a current is forced to flow from the drain to the source. At this instant, electrons flow from the source electrode 11 to the drain electrode 10 via the n-type high-concentration diffusion layer 4, n-type well diffusion layer 2, and Schottky barrier forming portion 6, as indicated by arrows 13. When the flow of electrons 13 exceeds a preselected value, holes begin to be injected into the well diffusion layer 2 from the edge of the p-type extended drain diffusion layer 5. The holes migrate due to the diffusion of the well diffusion layer 2 and finally flows into the p-type semiconductor substrate 1, as indicated by arrows 14. As the flow of electrons 13 further increases, the flow of holes 14 also increases and flows toward the center portion of the drain. This is because the increase of the flow of electrons 13 lowers the voltage (current x resistance) with the result that a forward bias great enough to overcome the built-in potential of the pn junction between the extended drain diffusion layer 5 and the well diffusion layer 2 begins to be applied from the edge of the diffusion layer 5. The built-in potential ranges from about 0.6 V to about 0.7 V in the case of silicon.

The flow of holes 14 from the drain electrode 10 into the substrate 1 constitutes a current that is not the subject of power collection. It is therefore desirable to reduce the flow 14 as far as possible. The FET 50 can reduce the flow 14 far more than a semiconductor device or a horizontal, insulated gate FET comparable in production cost with the FET 50. To further reduce the flow 14, a bias may be applied to the gate electrode 8 in such a manner as to cause the gate mechanism to form a conduction channel at the time of power collection, as will be described with reference to FIG. 8 hereinafter.

Power collection to occur when a bias is applied to the gate electrode 8, i.e., when the gate electrode 8 is connected to ground will be described with reference to FIG. 8. In the following description, the FET 50 is assumed to be in an ON state when a bias is applied to the gate electrode 8. As shown, 150 V is applied to the source electrode 11 while 0 V is applied to the gate electrode 8. 150 V plus X V higher than 150 V is applied to the drain electrode 10. To collect power, a current is forced to flow from the drain to the source. At this instant, electrons flow from the source electrode 11 to the drain electrode 10 via the n-type high-concentration diffusion layer 4, n-type well diffusion layer 2 and Schottky barrier forming portion 6 in accordance with the outside force, as indicated by arrows 13. In this case, the bias applied to the gate electrode 8 forms a channel right below the gate oxide film 9. The holes therefore flow via the p-type extended drain diffusion layer 5, channel below the gate oxide film 9 and p-type source high-concentration diffusion layer 3, as indicated by arrows 14.

In the FET 50, a voltage drop based on the product of a current and a resistance occurs in the portion where the holes flow in the same manner as in the portion where the electrons flow. As shown in FIG. 8, the voltage on the hole path 14 linearly varies from the p-type drain high-concentration layer to the p-type source high-concentration diffusion layer 3 via the p-type extended drain diffusion layer 5 and channel right below the gate oxide film 9 with respect to substantially horizontal displacement. On the other hand, the voltage on the electron path 13 substantially linearly varies from the Schottky barrier forming portion 6 to the n-type high-concentration diffusion layer 4 via the n-type well diffusion layer 2 with respect horizontal displacement. While electrons and holes flow in opposite directions and in parallel to each other, the voltages on the opposite paths 13 and 14 are of the same order with respect to horizontal displacement. This is sparingly influenced by the size of the current. It is therefore possible to noticeably reduce the injection of holes from the p-type diffusion layer and channel into the n-type diffusion layer 2 over a broad range of current values.

The illustrative embodiment can therefore sufficiently collect power when applied to a plasma display or an EL display and therefore saves the power and cost of such a display.

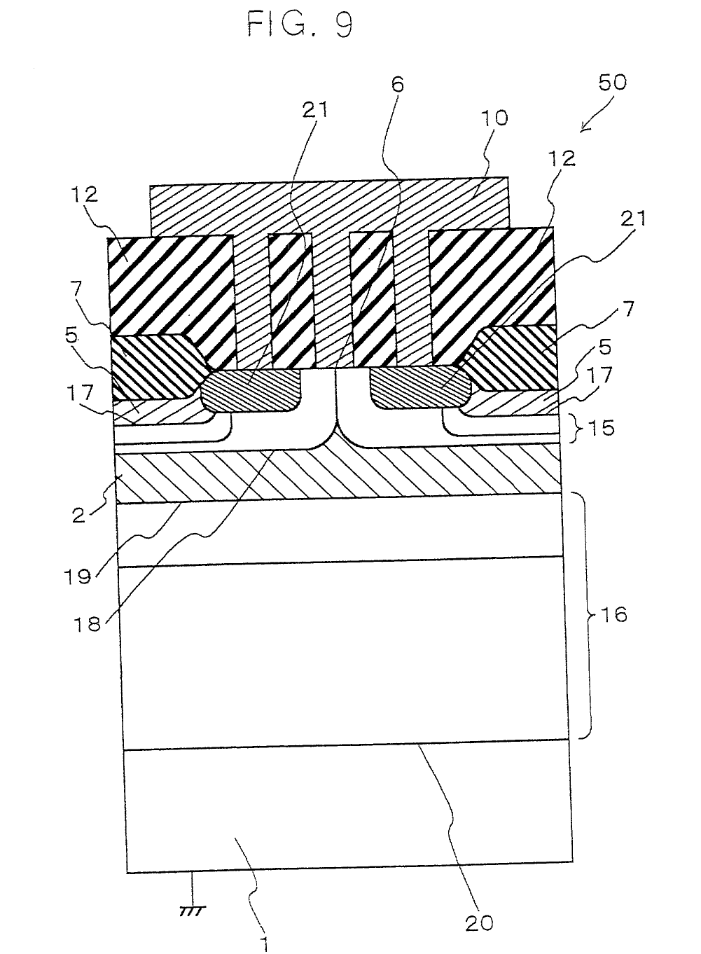

Depletion layers grow in the OFF state of the FET 50, as will be described hereinafter with reference to FIG. 9. FIG. 9 is an enlarged view showing how depletion layers grow around the drain in the OFF state of the FET 50, FIG. 4. In FIGS. 4 and 9, identical reference numerals designate identical structural elements. The condition shown in FIG. 9 is opposite to the conditions shown in FIGS. 7 and 8 as to the polarity of voltage between the drain and the source.

As shown in FIG. 9, in the OFF state of the FET 50, the pn junction between the p-type drain high-concentration diffusion layer 21 and the n-type well diffusion layer 2 around the drain is reversely biased. As a result, depletion layers start growing at the interface of the pn junction. Likewise, the Schottky barrier forming portion 6 is reversely biased, causing depletion layers to start growing at the Schottky barrier. Such depletion layers join each other and form depletion layers 15. At this instant, a voltage at a boundary 17 between the p-type extended drain diffusion layer 5 and the depletion layer 15 is 145 V. Also, a voltage at a boundary 18 between the depletion layer 15 and the n-type well diffusion layer 2 is 150 V. Generally, as for the reverse bias characteristics of a Schottky barrier, a leak current is great, and a withstanding voltage is low. More specifically, it is difficult to increase a yield voltage, so that the Schottky barrier is apt to break down after yielding. In the illustrative embodiment, the p-type drain high-concentration layer 21 surrounds the Schottky barrier forming portion 6 in order to solve the above problem. The illustrative embodiment can therefore make most of the merit of a forward bias (unipolar operation).

More specifically, the p-type drain high-concentration layer 21 surrounding the Schottky barrier forming portion 6 causes the depletion layers, which start growing at the layer 21 at the time of reverse bias, to pinch off below the portion 6. This prevents a reverse bias greater than the above reverse bias from being applied to the Schottky barrier. This principle itself has already been applied to, e.g., Schottky diodes for power. For details of this principle, reference may be made to the document (8) discussed earlier.

Further, a depletion layer 16 is formed because of the reverse bias applied to the p-type semiconductor substrate 1 and n-type well diffusion layer 2. A voltage at a boundary 19 between the diffusion layer 2 and the depletion layer 16 is 150 V while a voltage at a boundary between the depletion layer 16 and the substrate 1 is 0 V. While the depletion layers 15 and 16 may join each other in some diffusion layer structure, e.g., when the diffusion layer 2 is thinned, such an occurrence does not matter at all.

As stated above, the FET 50 can perform switching despite that the p-type drain high-concentration diffusion layer 21 surrounds the Schottky barrier forming portion 6 where the layer 21 is absent.

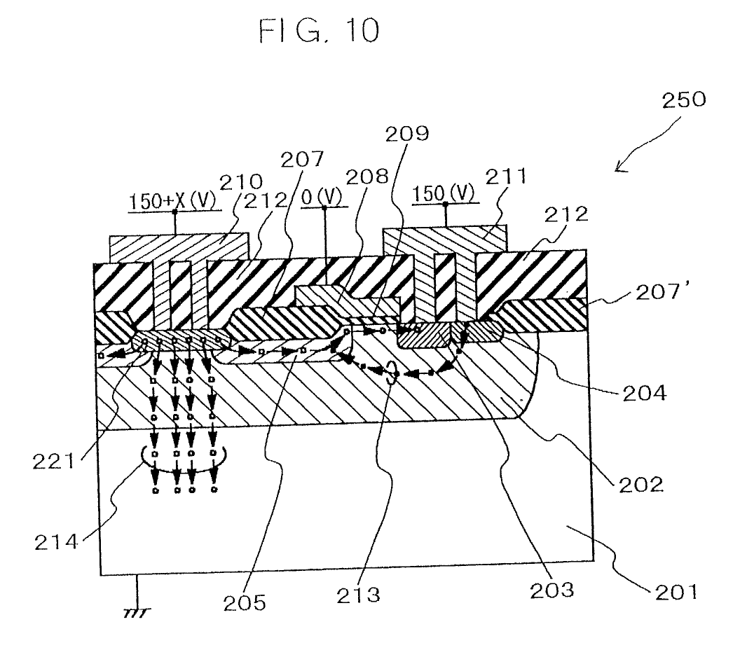

Assume that the FET driving method of the present invention is used to drive the conventional, insulated gate FET 250, FIG. 1. Then, as shown in FIG. 10, 150 V is applied to the source electrode 211. At the same time, 0 V is applied to the gate 208. Further, 150 V plus X V higher than 150 V appears on the drain electrode 210. At the time of power collection, a current is forced to flow from the drain to the source. A bias applied to the gate electrode 208 causes holes to flow through the channel as well. Electrons, however, sparingly flow in the n-channel well diffusion layer 202 around the portion right below the p-type extended drain diffusion layer 205 or the portion right below the p-type drain high-concentration diffusion layer 221, as indicated by arrows. Consequently, the voltage in the portion of the well diffusion layer 202 where current flows little remains constant. Further, when a great current flows, a flow of holes 214 causes the voltage of the drain diffusion layer 205 and that of the diffusion layer 221 to noticeably drop. This aggravates the injection of holes from the diffusion layer 221 to the well diffusion layer 202 over the built-in potential at the pn junction.

On the other hand, when the current is small, the voltage drop ascribable to the flow of holes 214 is not noticeable. Therefore, most of holes can flow from the p-channel drain high-concentration layer 212 to the source via the channel without being injected into the n-type well diffusion layer 202. In this condition, the conventional FET 250 can sufficiently reduce the current that cannot be collected. However, at the initial stage of power collection, an extremely great current flows through the FET 250. At this instant, the current exponentially decreases as the discharge from a load proceeds. On the other hand, the size of power collected decreases in proportion to the square of the above current. Consequently, the FET 250 is not effective during the interval of interest for collecting great power.

It will therefore be seen that the driving method of the present invention is not feasible for the conventional horizontal, insulated gate FET 250.

As stated above, in the illustrative embodiment, the n-type well diffusion layer 2 is formed on the surface of the p-type semiconductor substrate 1 in the form of an island. The p-type, horizontally elongate, insulated gate FET is formed on the surface of the diffusion layer 2. With this configuration, it is possible to collect power in order to save power to be consumed by a display panel. If desired, the p-type FET of the illustrative embodiment may be replaced with an n-type FET so long as it can collect power in order to reduce the power consumption of a display panel. The bias voltage, however, should preferably be reversed in polarity.

The illustrative embodiment achieves the following various unprecedented advantages. Power can be collected in order to save power to be consumed by a display panel. Power collection is achievable without resorting to an expensive component or an expensive process, e.g., an epitaxial substrate including buried diffusion layers or an SOI substrate including buried dielectric layers. This successfully reduces the power consumption and cost of a display. Further, switching can be effected without resorting to a switching device.

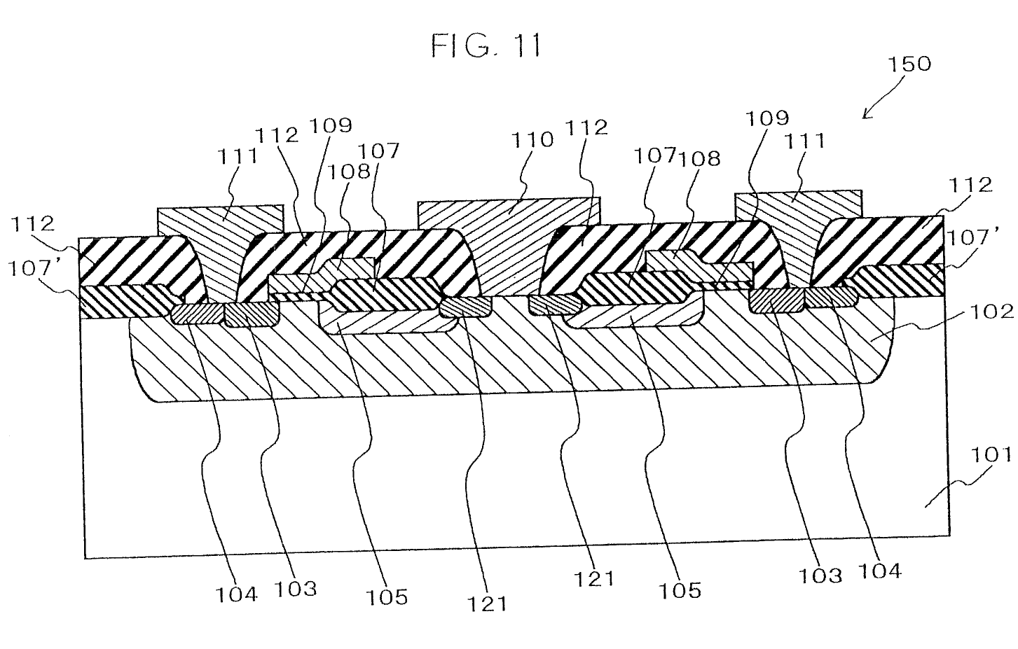

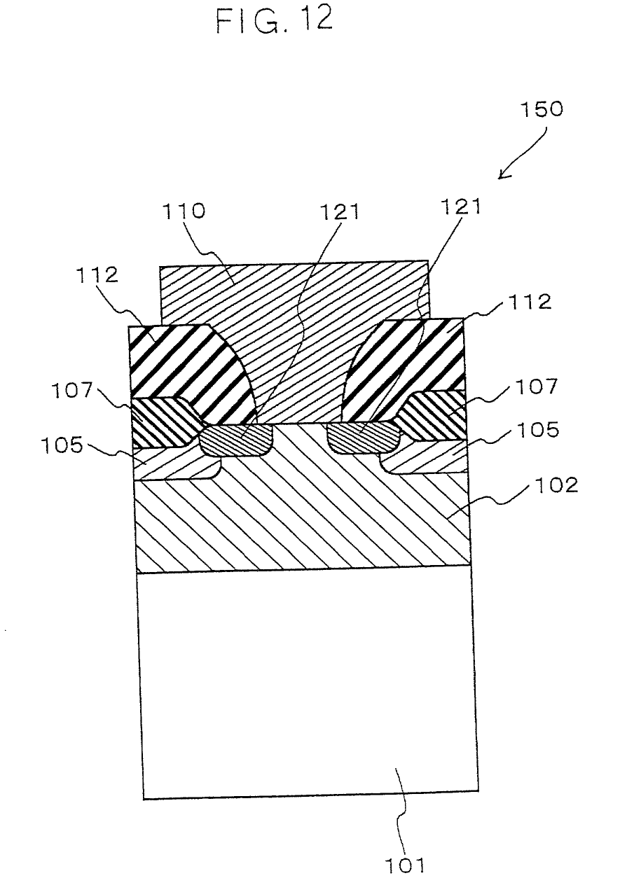

Referring to FIGS. 11 and 12, an alternative embodiment of the present invention will be described. Briefly, this embodiment differs from the previous embodiment in that it can be produced not only by the contact/plug process described above but also by a direct contact process, which directly connects a surface metal layer and a semiconductor layer. As for the FET driving method and power collection, this embodiment is identical with the previous embodiment. The following description will concentrate on the difference between the previous embodiment and this embodiment.

As shown in FIG. 11, a horizontal, insulated gate FET, generally 150, includes a p-type semiconductor substrate 101 in which boron is uniformly doped in a concentration of about 7×10¹⁴/cm³. Phosphor bronze is doped in the surface of the substrate 101 to a junction depth of 8 μm to 14 μm in a surface concentration of about 5×10¹⁵/cm³, forming an n-type well diffusion layer 102.

Two p-type source high-concentration diffusion layers 103, two n-type high-concentration diffusion layers 104 and two p-type extended drain diffusion layers 105 are formed on the surface of the well diffusion layer 102. The diffusion layers 103 and 104 are connected to each other. A p-type drain high-concentration diffusion layer 121 extends over part of the well diffusion layer 102 and part of one extended drain diffusion layer 105. Another p-type drain high-concentration diffusion layer 121 extends over another part of the well diffusion layer 102 and part of the other extended drain diffusion layer 105, as illustrated. In this configuration, the two diffusion layers 121 sandwich the island-like surface of the well diffusion layer 102.

A field oxide layer 107 is formed on the surface of the extended drain diffusion layers 105. The drain high-concentration diffusion layer 121 is connected to the extended drain diffusion layers 105 and field oxide film 107. A gate oxide film 109 is formed on the surface of the well diffusion layer 102 and the surfaces of the high-concentration diffusion layers 103 and connected to the field oxide film 107. A gate electrode 108 is formed on the surface of the field oxide film 107 and gate oxide film 109. A field oxide layer 107′, is formed on the substrate 101 and well diffusion layer 102 and connected to the high-concentration diffusion layers 104. The field oxide layers 107 and 107′ are formed by a single step.

An interlayer dielectric 112 is formed on the diffusion layers 103 and 104, field oxide layers 107 and 107′, gate electrode 108, and diffusion layer 121. The inter layer dielectric 112 is connected to the well diffusion layers 102, 102 and 104, field oxide film 107′, gate electrode 108, gate oxide film 109, and diffusion layer 121.

Holes are formed throughout the interlayer dielectric 112 for connecting the surfaces of the diffusion layers 103 and 104 to a source electrode 111. Another hole is formed throughout the interlayer dielectric 112 for connecting the diffusion layers 121, 102 and 110 and a drain electrode 110.

The source electrode 111 is formed on the surface of the interlayer dielectric film 112 and connected to the diffusion layers 103 and 104. The drain electrode 110 is also formed on the surface of the interlayer dielectric 112 and connected to the diffusion layers 121 and 102.

In the configuration shown in FIG. 11, a horizontal, high voltage, p-channel insulated gate FET is formed on the surface of the n-type well diffusion layer 102.

The direct contact process applicable to the illustrative embodiment will be described with reference to FIG. 12. As shown, in the illustrative embodiment, the source electrode 111 and drain electrode 110 and n-type well diffusion layer or semiconductor layer 102 are electrically connected together by the direct contact process.

Specifically, the interlayer dielectric 112 is grown on the surface of the n-type well diffusion layer 102. Subsequently, a single hole is formed in part of the interlayer dielectric 112 positioned above the p-type source high-concentration diffusion layer 103 and n-type high-concentration diffusion layer 104 by photolithography. At the same time, a single hole is formed in part of the interlayer dielectric 112 positioned above the region where the p-type drain high-concentration layers 121 are absent by photolithography. Thereafter, the source electrode 111 and drain electrode 110 and directly formed by using aluminum or similar metal. As a result, the source electrode 111 is connected to the diffusion layers 103 and 104 while the drain electrode 110 is connected to the diffusion layers 121 and 102.

As stated above, the horizontal, insulated gate FET 150 can be produced by the direct contact process in the same manner as produced by the contact/plug process. Although the drain region of the FET 150 differs from the drain region of the FET 50 produced by the contact/plug process, the former differs from the latter little as to electric characteristics. While the direct contact process includes a smaller number of steps than the contact/plug process, the former cannot implement miniaturization as easily as the latter. This is particularly true when it comes to a low-voltage SMOS transistor. The illustrative embodiment is feasible for applications of the kind in which the circuit scale of low-voltage SMOS transistors arranged on a single semiconductor substrate is relatively small.

As stated above, in the illustrative embodiment, the p-type, horizontally elongate, insulated gate FET is formed on the surface of the n-type well diffusion layer 2 by the direct contact process. With this configuration, it is possible to collect power in order to save power to be consumed by a display panel. Again, the p-type FET may be replaced with an n-type FET so long as it can collect power in order to reduce the power consumption of a display panel. The bias voltage, however, should preferably be reversed in polarity.

The illustrative embodiment can implement a production process matching with a circuit scale, while achieving the same advantages as the previous embodiment.

In summary, it will be seen that the present invention realizes power collection for saving power to be consumed by a display panel.

Various modifications will become possible for those skilled in the art after receiving the teachings of the present disclosure without departing from the scope thereof.

What is claimed is:

1. A horizontal, insulated gate field effect transistor (FET) comprising:
a semiconductor substrate of a first conductivity;
a well region of a second conductivity formed on a surface of said semiconductor substrate;
a source region of the first conductivity formed in said well region;
a source electrode connected to said source region;
a drain region of the first conductivity formed in said well region;
a gate dielectric formed on said we region and extending over said source region and said drain region; and
a gate electrode formed on said gate dielectric;
wherein said drain electrode is connected to said well region at a position other than said drain region.

2. The FET as claimed in claim 1, wherein said drain region comprises a plurality of diffusion layers including a first drain diffusion layer and a second drain diffusion layer.

3. The FET as claimed in claim 2, wherein said drain electrode is connected to said well region at a position between said first drain diffusion layer and said second drain diffusion layer.

4. The FET as claimed in claim 1, further comprising a field oxide layer formed between said source region and said drain region, wherein said gate dielectric is connected to said field oxide film while said source region extends below said field oxide layer to a position below said gate dielectric.

5. The FET as claimed in claim 1, wherein said drain electrode comprises a first drain electrode, a second drain electrode and a third drain electrode,
said third drain electrode is connected to said first drain electrode and said second drain electrode,
said first drain electrode and said second drain electrode are connected to said drain region, and
said third drain electrode does not contact said first drain electrode or said second drain electrode on said well region and is connected to said well region at a position other than said drain region.

6. The FET as claimed in claim 5, wherein said drain region comprises a plurality of diffusion layers including a first drain diffusion layer and a second drain diffusion layer,
said first drain electrode is connected to said first drain diffusion layer, and
said second drain electrode is connected to said second drain diffusion layer.

7. The FET as claimed in claim 6, wherein said third drain electrode is connected to said well region between said first drain diffusion layer and said second drain diffusion layer.

8. In a semiconductor device comprising a plurality of horizontal, insulated gate FETs for driving capacitive loads, said horizontal, insulated gate FETs each comprising:
a semiconductor substrate of a first conductivity;
a well region of a second conductivity formed on a surface of said semiconductor substrate;
a source region of the first conductivity formed in said well region;
a source electrode connected to said source region;
a drain region of the first conductivity formed in said well region;
a gate dielectric formed in said well region and extending over said source region and said drain region; and
a gate electrode formed on said gate dielectric;
wherein said drain electrode is connected to said well region at a position other than said drain region.

9. The device as claimed in claim 8, wherein said drain region comprises a plurality of diffusion layers including a first drain diffusion layer and a second drain diffusion layer.

10. The device as claimed in claim 9, wherein said drain electrode is connected to said well region at a position between said first drain diffusion layer and said second drain diffusion layer.

11. The device as claimed in claim 8, further comprising a field oxide layer formed between said source region and said drain region, wherein said gate dielectric is connected to said field oxide film while said source region extends below said field oxide layer to a position below said gate dielectric.

12. The device as claimed in claim 8, wherein said drain electrode comprises a first drain electrode, a second drain electrode and a third drain electrode,
said third drain electrode is connected to said first drain electrode and said second drain electrode,
said first drain electrode and said second drain electrode are connected to said drain region, and
said third drain electrode does not contact said first drain electrode or said second drain electrode on said well region and is connected to said well region at a position other than said drain region.

13. The device as claimed in claim 8, wherein said drain region comprises a plurality of diffusion layers including a first drain diffusion layer and a second drain diffusion layer,
said first drain electrode is connected to said first drain diffusion layer, and
said second drain electrode is connected to said second drain diffusion layer.

14. The device as claimed in claim 13, wherein said third drain electrode is connected to said well region between said first drain diffusion layer and said second drain diffusion layer.

15. In a horizontal, insulated gate FET device comprising a first horizontal, insulated gate FET and a second horizontal, insulated gate FET, said first horizontal, insulated gate FET comprising:
a semiconductor substrate of a first conductivity;
a well region of a second conductivity formed on a surface of said semiconductor substrate;
a first source region of the first conductivity formed in said well region;
a first source electrode connected to said first source region;
a first source electrode connected to said first source region;
a first drain region of the first conductivity formed in said well region;
a first drain electrode connected to said first drain region;
a first gate dielectric formed on said well region and extending over said first source region and said first drain region; and
a first gate electrode formed on said first gate dielectric;
said second horizontal, insulated gate FET comprising:
a second source region of the first conductivity formed in said well region;
a second source electrode connected to said second source region;
a second drain region of the first conductivity formed in said well region;
a second drain electrode connected to said second drain region;
a second gate dielectric formed on said well region and extending over said second source region and said second drain region; and
a second gate electrode formed on said second gate dielectric;
wherein said fist horizontal, gate insulated FET and said second horizontal, gate insulated FET share a third drain electrode connected to said first drain electrode and said second drain electrode, and
said third drain electrode is connected to said well region at a position other than said first drain region and said second drain region.

16. The device as claimed in claim 15, wherein said third drain electrode does not contact said first drain electrode or said second drain electrode on said well region and is connected to said well region at a position other than said first drain region and said second drain region.

17. The device as claimed in claim 16, where in said first drain region comprises a plurality of diffusion layers including a first drain diffusion layer,
said second drain region comprises a plurality of diffusion layers including a second drain diffusion layer,
said first drain electrode is connected to said first drain diffusion layer, and
said second drain electrode is connected to said second drain diffusion layer.

18. The device as claimed in claim 17, where in said third drain electrode is connected to said well region between said first drain diffusion layer and said second drain diffusion layer.

19. The device as claimed in claim 15, wherein said first FET further comprises a first field oxide layer formed between said first source region and said first drain region,
said first gate dielectric being connected to said first field oxide film,
said first source region extends below said first field oxide film to a position below said first gate dielectric;
said second FET further comprises a second field oxide film formed between said second source region and said second drain region,
said second gate dielectric is connected to said second field oxide film, and
said second source region extends below said second field oxide film to a position below said second gate dielectric.

20. A method of driving a horizontal, insulated gate FET, comprising the steps of:
(a) preparing said horizontal, insulated gate FET comprising a semiconductor substrate of a first conductivity, a well region of a second conductivity formed on a surface of said semiconductor substrate, a source region of the first conductivity formed in said well region, a source electrode connected to said source region, a drain region of the first conductivity formed in said well region, a gate dielectric formed in said well region and extending over said source region and said drain region, and a gate electrode formed on said gate dielectric, wherein said drain electrode is connected to said well region at a position other than said drain region;
(b) applying a periodic, first voltage to said source electrode; and
(c) applying, when said first voltage is being applied to said source electrode in step (b), a second voltage different in period from said first voltage to said gate electrode to thereby form a conduction channel right below said gate dielectric.
